(19) United States
(12) Patent Application Publication
(10) Pub. No.: US 2014/0239473 A1
(43) Pub. Date: Aug. 28, 2014

(54) WIRE BONDING ASSEMBLY AND METHOD

(71) Applicant: TEXAS INSTRUMENTS INCORPORATED, Dallas, TX (US)

(72) Inventor: MengThee Chia, Selangor (MY)

(73) Assignee: TEXAS INSTRUMENTS INCORPORATED, Dallas, TX (US)

(21) Appl. No.: 13/781,244

(22) Filed: Feb. 28, 2013

(51) Int. Cl. H01L 23/00; H01L 23/495

(52) U.S. Cl. CPC H01L 24/85; H01L 23/4952
USPC 257/676; 438/123

(57) ABSTRACT

A method of wire bonding a die to a lead frame comprising mounting the die on a die attachment pad portion of a leadframe and supporting the leadframe on a support plate having a vacuum hole therein filled with porous material.

### BACKGROUND

Wire bonding is a frequently used method of connecting an IC die to a leadframe. One end of a bond wire is welded to a contact pad of the die and the other end of the bond wire is welded to the leadframe. There are two main classes of wire bonding: ball bonding and wedge bonding. Each typically uses some combination of heat, pressure and ultrasonic energy to make a weld. A ball bond is most often used to make the connection between the bond wire and a die. Wedge bonding is used most often to connect the bond wire to a leadframe. Bond wires are typically made from copper or gold. The diameter of the bond wire used may be as small as 15 μm. A tool used to perform wire bonding dispenses the bond wire from a needle like device called a capillary. In forming a ball bond the capillary melts a small length of wire near its tip to form a molten ball. The molten ball is then pressed against a contact pad on the die by the capillary, which is then pulled away to form a ball bond on the contact pad. As the capillary is moved away from the contact pad it dispenses wire, which remains connected to the ball bond. The capillary then moves to a position over a leadframe where it forms another bond, usually a wedge bond, to electrically connect the die to the leadframe.

### BRIEF DESCRIPTION OF THE DRAWINGS

FIG. 1 is a schematic, cutaway, exploded view of a prior art quad flat no leads package (QFN).

FIG. 2 is a bottom isometric view of a prior art QFN.

FIG. 3 is a top plan view of a prior art leadframe strip.

FIG. 4 is a top plan view of one leadframe panel of the prior art leadframe strip of FIG. 4.

FIG. 5 is a top plan view of a prior art support plate adapted to support the leadframe panel of FIG. 4.

FIG. 6 is a schematic cross sectional view of a prior art wire bonding assembly.

FIG. 7 is a top perspective photograph of an IC die.

FIG. 8 is a schematic cross sectional view of a new wire bonding assembly.

### DETAILED DESCRIPTION

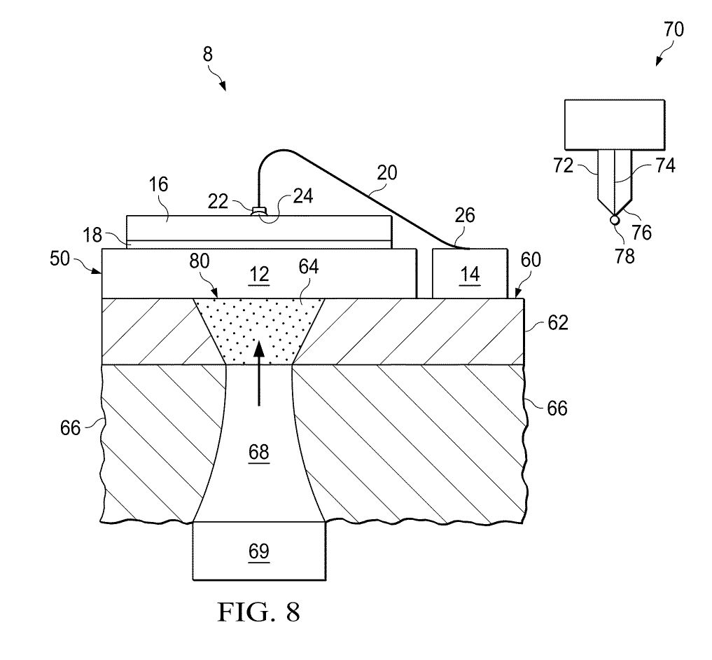

This specification, in general, discloses an integrated circuit (IC) package wire bonding assembly 8, FIG. 8. This assembly 8 includes a leadframe support plate 60 having a vacuum hole 64 extending therethrough. Porous filler material 80 is inserted in the vacuum hole 64. The assembly 8 also includes a leadframe 50 having a die attachment pad portion 12 and lead portions 14 integrally attached to the die attachment pad portion 12. The leadframe 50 is supported by the support plate 60 with the die attachment pad portion 12 covering the vacuum hole 64. Having thus generally described an IC package wire bonding assembly 8, the assembly and associated methods of wire bonding will now be described in further detail.

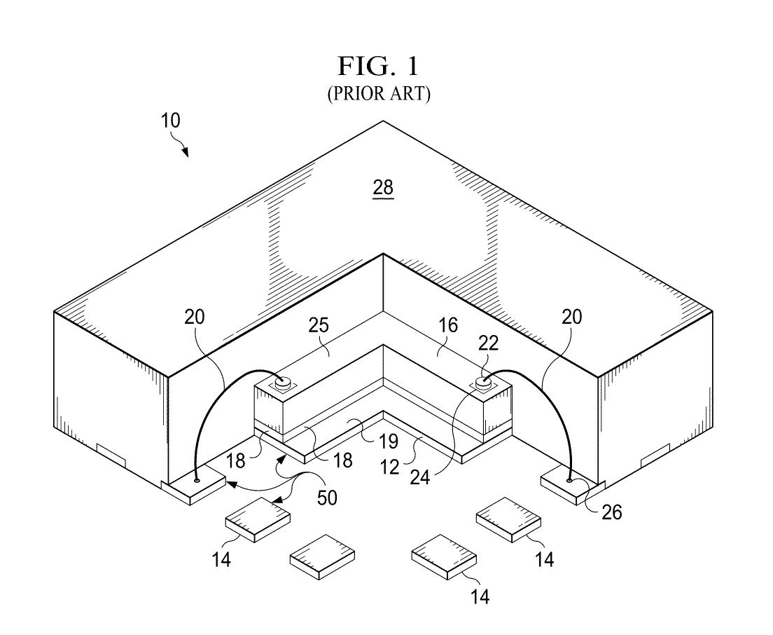

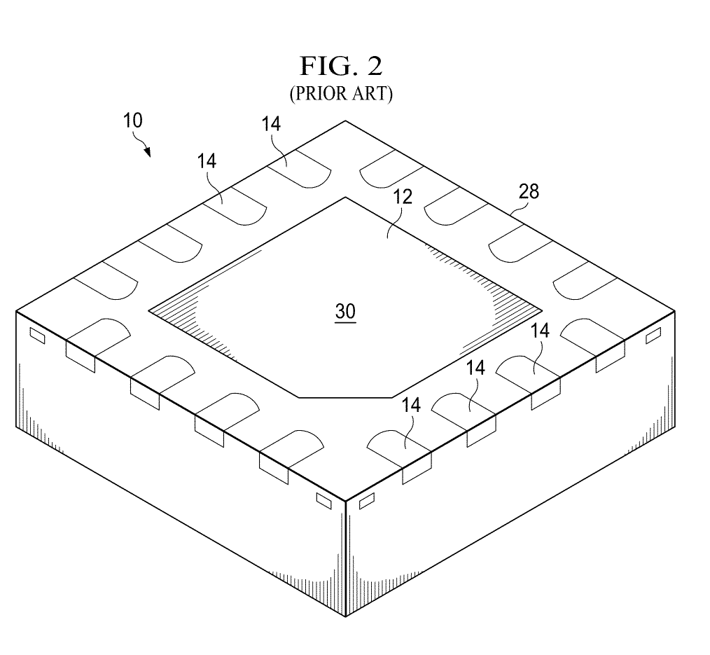

FIG. 1 illustrates a prior art quad flat no leads package (QFN) 10. FIG. 2 is a bottom view of the QFN 10 of FIG. 1. As shown in FIG. 1, a die attachment pad (DAP) portion 12 of a leadframe 50 is positioned in spaced apart relationship with a plurality of lead portions 14 of the leadframe 50. An integrated circuit (IC) die 16 is attached to the DAP portion 12 with a die bond material 18 applied to the top surface 19 of the DAP portion 12. A plurality of bond wires 20 are attached to contact pads 24 on the top surface 25 of an integrated circuit (“IC”) die 16 by ball bonds 22. The other ends of the bond wires 20 are attached by wedge (stitch) bonds 26 to a leads 14. The IC die 16 and attached DAP portion 12 and the bond wires 21 are held in fixed relationship with respect to lead portions 14 by a layer of encapsulant 28. The encapsulant completely 28 covers the IC die 16 and bond wires 20 while exposing the bottom surface 24 of the DAP portion 12 and the bottom and edge surfaces of the lead portions 14, as shown in FIG. 2.

One method of making QFNs involves removing the DAP portion 12 and the lead portions 14 from a leadframe and then placing them in predetermined positions on a strip of tape. The tape thus supports the DAP portion 12 and the lead portions 14 in the required spacing prior to encapsulation. During wire bonding the tape is supported on a porous plate. A vacuum is applied through the porous plate across the entire bottom surface of the tape to hold it to the porous plate. The tape must be removed after encapsulation. The steps of placing the DAP and leads on the tape before wire bonding and then removing the tape after encapsulation adds significant cost to QFN production

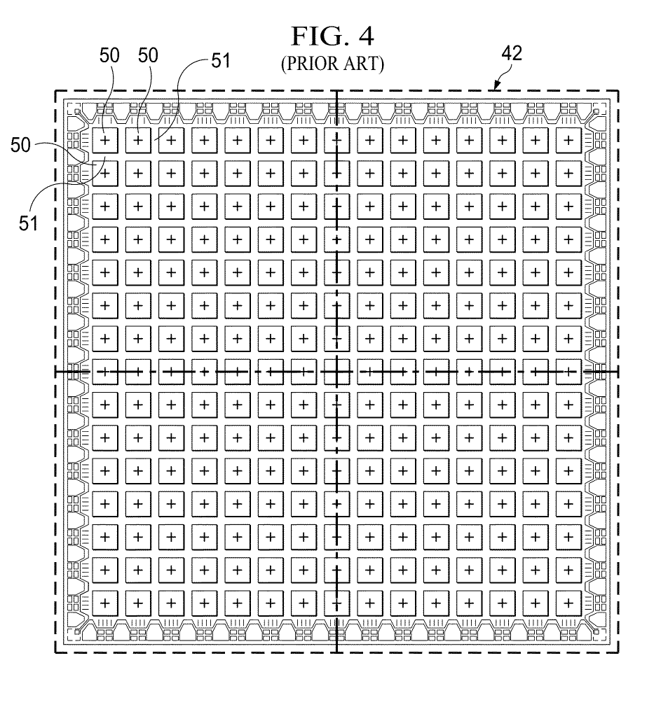

Another method of making QFNs is to perform the die attach, wire bonding and encapsulation steps when the DAP portion 12 and lead portions 14 are each still integrally connected parts of a leadframe 50. Lead frames 50 are shown schematically in FIG. 4 by a square with a “+” symbol in it. The various shapes of QFN leadframes are well known in the art and are thus not further described herein. The leadframe 50 is connected to a plurality of other identical leadframes 50. The DAP 12 and leads 14 are integrally connected by webbing at the periphery of each leadframe 50. This peripheral webbing is trimmed away after die attach, wire bonding, and encapsulation in a process known as singulation or dicing. In a typical 3 mm×3 mm QFN 10, the leadframe 50 is 3 mm×3 mm and may be stamped from a copper sheet. The DAP 12 is generally square in shape and may have x,y dimensions of about 1.9 mm×1.9 mm for a 3 mm×3 mm package.

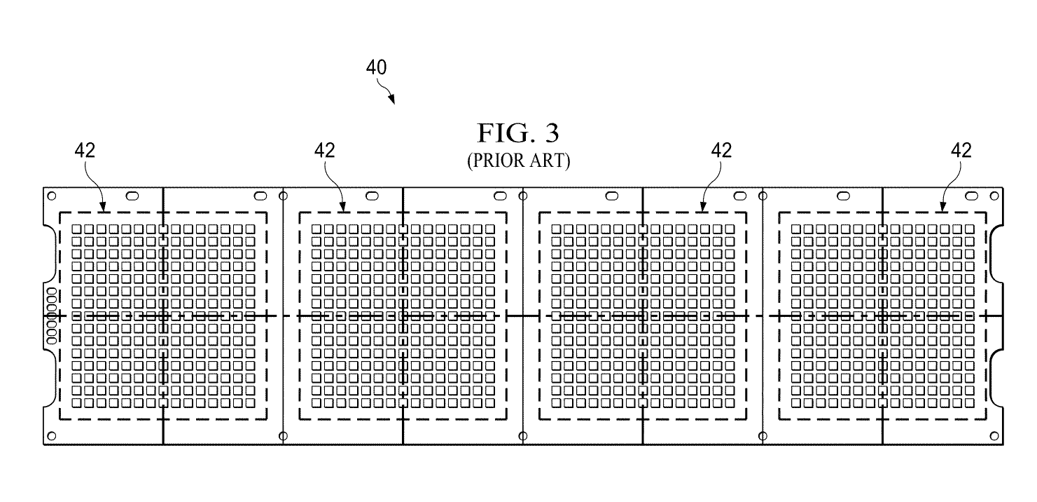

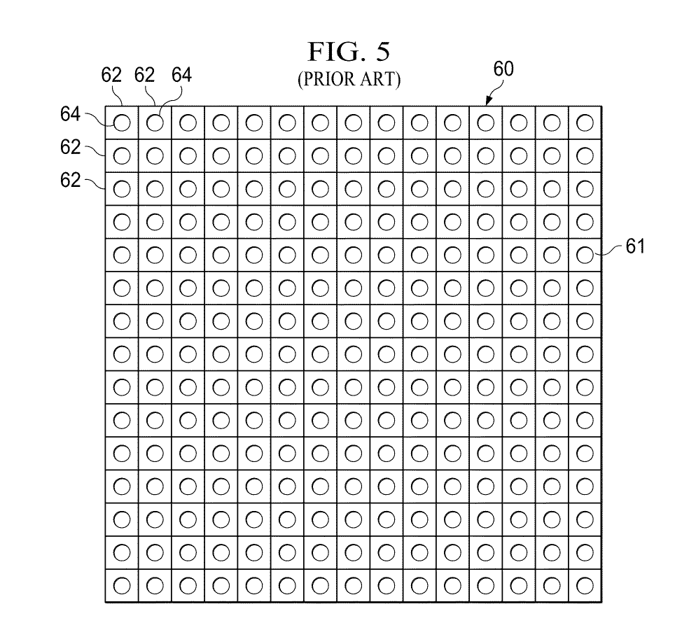

In a typical QFN 10 forming process of the type described in the previous paragraph, lead frames 50 are initially provided in a lead frame strip 40 that includes a plurality of leadframe panels 42, FIG. 3. Each leadframe panel 42 includes a plurality of interconnected lead frames 50 as shown in FIG. 4. (The leadframes 50 in this interconnected state are sometimes referred to in the art as “leadframe units.” In this specification “leadframe” is used to refer to a leadframe in both the interconnected and separated states thereof.) The lead frames 50 within each leadframe panel 42 are connected to one another by peripheral lead portions or webbing (detail not shown) as is well known in the art. In the illustration of FIG. 4, the leadframe panel 42 is 15 lead frames wide and 15 leadframes long. Each leadframe 50 includes a die pad portion 12 and a plurality of lead portions 14 attached to peripheral webbing. Various operations are performed on the individual leadframes 50 while the leadframes 50 are in the leadframe strip 40. Such operations include die bonding, wire bonding, encapsulation and finally singulation. The panels 42 are placed on a supporting surface during wire bonding. An individual lead frame 50 is held in place by a clamping arrangement for larger leadframes. However, for QFNs of about 5 mm×5 mm and smaller, such clamping arrangements cannot be used. Therefore, smaller QFNs require a clamping design that clamps the periphery of an entire panel 42. Thus, a typical panel 42 having, e.g., 15×15 units, is clamped only at the periphery of the panel 42. In this situation vacuum suction is relied on to stabilize the DAPs 12 during wire bonding. The panel 42 is supported on a support plate 60. The support plate 60 has a top surface 61 and comprises a plurality of leadframe support units 62, FIG. 5. Each support unit 62 has a vacuum hole 64 extending therethrough. The leadframe panel 42 is positioned on the leadframe support plate 60 so that each leadframe 50 is positioned directly over a corresponding leadframe support unit 62. Each DAP portion 12 of a leadframe 50 is positioned over a corresponding vacuum hole 64. The vacuum hole 64 over which the DAP 12 is positioned has a generally truncated cone shape and, in one embodiment is about 1 mm in diameter at the top surface 61 of the plate 60.

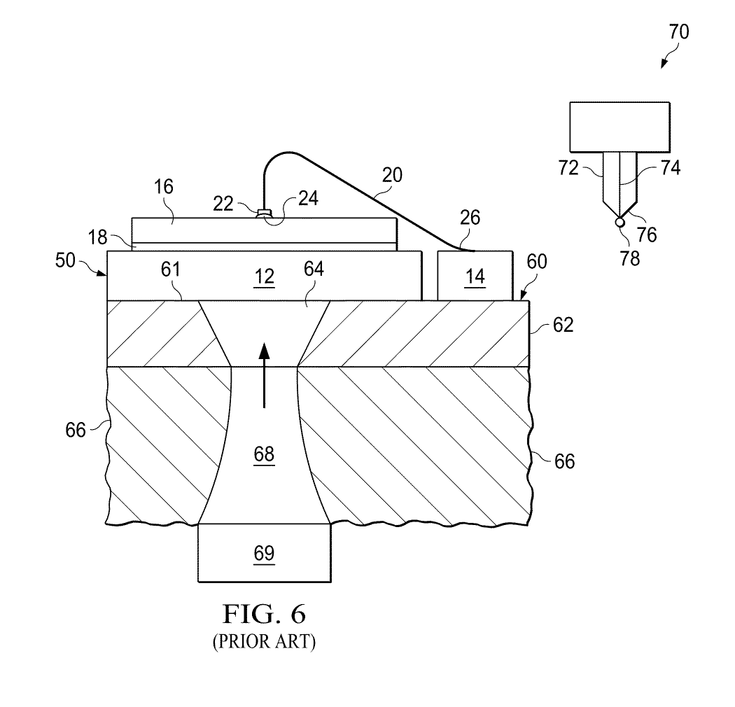

FIG. 6 schematically illustrates a typical prior art wire bonding operation. The leadframe support plate 60 is positioned on a heating unit 66 having a passage way 68 extending therethrough with the vacuum hole 64 in the leadframe support plate unit 62 at one end and a vacuum source 69 at the other end. The leadframe lead portions 14 are supported on the top surface 61 of the leadframes support unit 62 adjacent to the die pad 12.

A conventional wire bonder machine 70 includes a capillary 72 which dispenses a thin wire 74 which may be a gold wire about 20.3 μm-50.3 μm in diameter from a tip 76 of the capillary 72. The capillary 72 also has a heating source (not shown) which can selectively apply heat to a small length of the wire 74 extending from the capillary tip 76. The heat causes the small length of wire to be transformed into a molten ball 78 at the capillary tip 76. During wire bonding, the capillary 72 is lowered to the die 12 and presses the molten ball 78 against a contact pad 24 on the die 12 to form a ball bond 22 that securely bonds the bond wire 20 to the die contact pad 24. During the ball bonding operation a vacuum is applied through the vacuum hole 64 to hold the DAP portion 12 securely in place on the leadframe support unit 62. It will of course be understood that each of the multiple support units 62 have a leadframe 50 supported thereon and the vacuum is applied to the corresponding vacuum holes 64 in all of these support units 62. Ball bonding is done one die at a time and one bond at a time until all bonding pads for each die are completely bonded. All vacuum holes 64 are connected to the same vacuum source and thus the vacuum is either “on” or “off” for all vacuum holes 64.

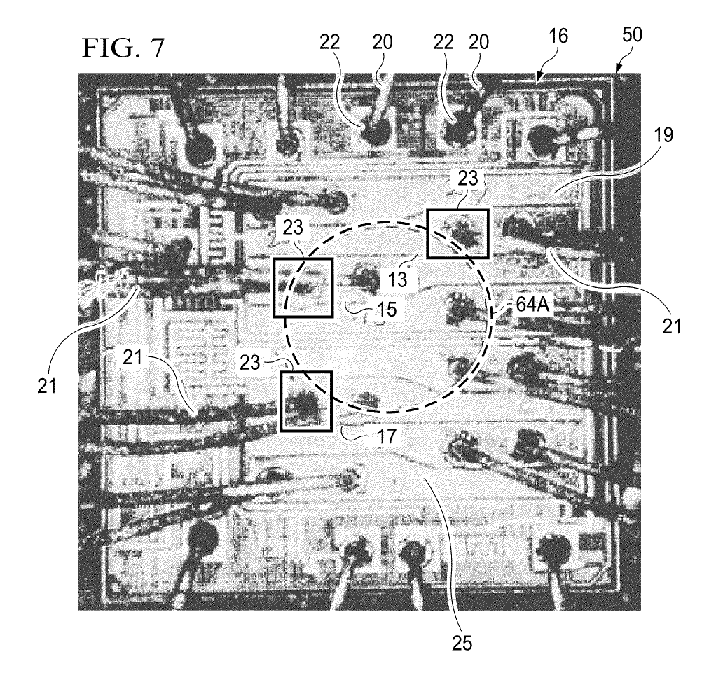

Applicant has discovered that for small DAPs, e.g. about 3 mm×3 mm and smaller, the above described method of holding a DAP in place during ball bonding may produce defective ball bonds. FIG. 7 is a photograph of a die 16 on which defective ball bonds 23 were formed using a ball bonding assembly such as shown in FIG. 6. As may be seen from FIG. 7, the defective ball bonds 23 associated with the three lead wires 21 are flattened and irregular in shape and spread laterally farther than normal ball bonds 22. As a result of this undesirable spreading, the defective ball bonds 23 have come into contact with traces 13, 15 and 17 on the top surface 25 of the die 16, resulting in short circuits. It will also be seen from FIG. 7 that the defective ball bonds 23 all occur near an imaginary circle 64A that is positioned directly over the periphery of the vacuum hole 64. It is applicant's theory that the unsupported portion of the DAP portion 12 over the vacuum hole 64 elastically deforms when the capillary tip 76 presses down on the die pads 24 during bonding and then snaps back when the capillary 74 is removed. Applicant has also discovered that the top surface of the DAP portion 12 tends not to stick to the die 16 within the area of this circle 64A.

Applicant's solution to the above discussed problem is illustrated in FIG. 8, in which the same reference numerals are used as in FIG. 6 for structures that are the same as in FIG. 6. The structure of the wire bonding assembly 8 of FIG. 8 may be the same as the wire bonding assembly illustrated in FIG. 6, except that rather than being empty the vacuum hole 64 in FIG. 8 is filled with a porous material insert 80. The porous material insert 80 allows a vacuum to be applied to the DAP portion 12, but provides vertical support to the DAP portion 12 positioned over the filled vacuum hole 64. This structure substantially eliminates elastic deformation of the DAP portion 12 and bounce during ball bonding that may cause defective ball bonds and nonstick between a region of the DAP portion 12 and the die 16. Any porous material insert 80 that provides a relatively smooth support surface and that allows the passage of sufficient vacuum to hold the DAP portion 12 in place during bonding may be used.

Thus, an assembly 8 and associated method have been described that eliminate ball bonding defects in small QFN packages without resorting to the more time consuming and expensive tape based technique.

Although an embodiment of an IC package wire bonding assembly and method have been disclosed in detail herein, various other embodiments thereof will become obvious to those skilled in the art after reading this disclosure. It is intended that the claims appended hereto be construed broadly to cover all such alternative embodiments except to the extent limited by the prior art.

1. An integrated circuit (“IC”) package wire bonding assembly comprising:
a leadframe support plate having a vacuum hole, positioned and centered directly under the center portion of a die attachment pad, extending therethrough; and
a porous filler material positioned in said vacuum hole, configured to provide vertical support for the center of the die attachment pad structure and substantially eliminating elastic deformation of the die attachment pad and bounce during ball bonding.

2. The assembly of claim 1 further comprising:
a leadframe having a die attachment pad portion and lead portions integrally attached to said die attachment pad portion, said leadframe being supported by said plate with said die attachment pad portion thereof covering said vacuum hole; and
a die attached to said leadframe die attachment pad portion, said die having at least one contact pad.

3. The assembly of claim 2 further comprising a wire bonder operable to form a wire bond on said contact pad of said die.

4. The assembly of claim 3, said wire bond being positioned at one end of a bond wire having a second end bonded to one of said lead portions.

5. The assembly of claim 4, said leadframe support plate comprising a plurality of vacuum holes filled with said porous filler material and further comprising a plurality of leadframes with die attachment pad portions of each positioned over corresponding ones of said plurality of filled vacuum holes.

6. A method of wire bonding an IC die having a contact pad to a lead frame comprising:
mounting the IC die on a die attachment pad portion of a leadframe; and
supporting the leadframe on a support plate having a vacuum hole, wherein the vacuum hole is positioned and centered directly under the center portion of a die attachment pad, the vacuum hole is filled with a porous filler material, wherein the porous filler material is configured to provide vertical support for the center of the die attachment pad and substantially eliminating elastic deformation of the die attachment pad and bounce during ball bonding.

7. The method of claim 6 wherein said supporting the leadframe comprises positioning the die attachment pad portion of the leadframe over the vacuum hole.

8. The method of claim 7 further comprising forming a molten ball at one end of a lead wire and ball bonding the molten ball to a contact pad on the IC die.

9. The method of claim 8 further comprising heating the IC die.

10. The method of claim 9 wherein said heating the IC die comprises heating the support plate.

11. A method of making a quad flat no lead (“QFN”) package comprising:
providing a leadframe support plate having a vacuum hole, positioned and centered directly under the center portion of a die attachment pad, extending therethrough;
filling the vacuum hole in the support plate with a porous material;
providing a leadframe strip having a plurality of integrally connected leadframes; and
moving the die attachment pad portion of one of the leadframes in the leadframe strip to a location directly above the filled vacuum hole.

12. The method of claim 11 further comprising applying a vacuum through the filled vacuum hole to the die attachment pad portion of the leadframe.

13. The method of claim 12 further comprising wire bonding a first end of a bond wire to a contact pad on an IC die attached to the die attachment pad portion.

14. The method of claim 13 further comprising bonding a second end of the bond wire to a lead portion of the leadframe.

15. The method of claim 11 further comprising heating the support plate.

16. The method of claim 13 wherein said wire bonding one end of a bond wire comprises ball bonding one end of a copper bond wire.

17. The method of claim 13 wherein said wire bonding one end of a bond wire comprises ball bonding one end of a gold bond wire.

18. The method of claim 13 further comprising encapsulating the IC die, bond wires and portions of the leadframe in a mold compound.

19. The method of claim 18 further comprising singulating the encapsulated die, bond wires and partially encapsulated leadframe from other leadframes on the leadframe strip.

20. The method of claim 18 further comprising plating the portions of the leadframe that are not encapsulated.
